(19) United States
(12) Patent Application Publication
(10) Pub. No.: US 2024/0132339 A1
(43) Pub. Date: Apr. 25, 2024

(54) Microelectromechanical Device for Generating Sound Pressure

(71) Applicant: Robert Bosch GmbH, Stuttgart (DE)

(72) Inventors: Markus Klemm, Dresden (DE); Anartz Unamuno, Dresden (DE)

(21) Appl. No.: 18/487,706

(22) Filed: Oct. 15, 2023

(30) Foreign Application Priority Data
Oct. 24, 2022 (DE) DE102022128242.2

(51) Int. Cl. B81B 3/00

(52) U.S. Cl. CPC B81B 3/0027; B81B 2201/0257

(57) ABSTRACT

Embodiments generally relate to drives for microelectromechanical devices for generating a sound pressure that can be implemented in a microelectromechanical system (MEMS). The movable legs of the actuators are connected to one another by means of connecting elements and form a lateral surface, the volume of which can be changed by the movement of the legs to generate a sound pressure.

### PRIORITY CLAIM

This application is based on and claims priority of German patent application DE 10 2022 128 242.2 filed on Oct. 25, 2022, the entire content of which is incorporated herein by reference.

### TECHNICAL FIELD

Embodiments generally relate to drives for microelectromechanical devices for generating a sound pressure that can be implemented in a microelectromechanical system (MEMS). In some embodiments, the microelectromechanical device for generating a sound pressure is implemented in a chip/die, e.g. in the form of a system-on-chip (SoC) or a system-in-package (SiP). Further embodiments relate to the use of such a microelectromechanical device for generating a sound pressure in a microelectromechanical loudspeaker system, e.g. in a headphone, a hearing aid or the like.

### BACKGROUND

The working principles of a nanoscopic electrostatic drive (NED) is described in WO 2012/095185 A1. NED is based on a MEMS-based actuator principle. The movable elements which form the actuators are formed from a semiconductor material, for example silicon material, which has at least two electrodes spaced-apart from each other. Without limitation in this respect, other semiconductor materials can also be used. The length of the electrodes is much greater than the thickness of the electrodes and the height of the electrodes, i.e. the dimension along the depth direction of the silicon material. These rod-shaped electrodes are spaced apart from each other and are fixed in a manner locally electrically insulated from each other. By applying an electric potential, an electric field is generated between these electrodes, which leads to attractive or repulsive forces between the electrodes and thus to stresses in the material of the electrodes. The material attempts to homogenize these stresses by assuming a low-stress state, which leads to a movement. By means of a specific geometry and topography of the electrodes, this movement can be influenced in such a way that the electrodes change in length and thus a lateral movement of the deflectable element takes place.

Implementations and improvements of microelectromechanical devices that use a NED are described in the prior art, e.g. in WO 2016/202790 A2, WO 2020/078541 A1, WO 2022/117197 A1, WO 2021/223886 A1, etc., which are each incorporated herein by reference. In these microelectromechanical devices, a plurality of actuators moving in the plane cause a change in an air volume located between the actuators and thus generate a sound pressure. These microelectromechanical devices can be used as acoustic transducer systems worn in the ear. The modulation of the air volume between the actuators generates an audible sound inside the ear canal.

WO 2022/117197 A1 shows a MEMS component that comprises a layer stack with a plurality of MEMS layers. The MEMS component comprises a movable element (actuator) formed in a first MEMS layer, which is arranged in a cavity between a second MEMS layer and a third MEMS layer of the layer stack. Furthermore, a drive device is provided, which has a first drive structure which is mechanically fixedly connected to the movable element and a second drive structure mechanically which is fixedly connected to the second MEMS layer. The drive device generates a drive force on the movable element that is perpendicular to the layers' direction. The drive force deflects the movable element.

WO 2021/223886 A1 also shows a MEMS component that comprises a layer stack with a plurality of MEMS layers. The MEMS comprises an interaction structure arranged movably in a first MEMS plane and in the cavity along a plane direction in order to interact with a fluid (e.g. air) in the cavity. A movement of the interaction structure is causally related to a movement of the fluid through the at least one opening. The MEMS further comprises an active structure arranged perpendicular to the plane direction in a second MEMS plane. The active structure is mechanically coupled to the insulation structure and is configured such that an electrical signal at an electrical contact of the active structure is causally related to a deformation of the active structure. The deformation of the active structure is in turn causally related to the movement of the fluid.

WO 2016/202790 A2 shows a further MEMS transducer for interacting with a volume flow of a fluid, which comprises a substrate having a cavity. The MEMS transducer further comprises an electromechanical transducer (actuator) which is connected to the substrate in the cavity and has an element which is deformable along a lateral movement direction. Deformation of the deformable element along the lateral movement direction and the volume flow of the fluid are causally related to each other.

### BRIEF SUMMARY

This brief summary is provided to introduce a selection of concepts in a simplified manner that are described in more detail below in the detailed description. This summary is not intended to identify any key features or essential features of the claimed subject matter.

Some of the embodiments aim to reduce the forces necessary for deflecting the active actuator structures in a microelectromechanical device in order to generate a sound pressure. In doing so, the acoustic performance of the microelectromechanical device should not be reduced as far as possible.

One aspect of this disclosure is to design an actuator for use in a microelectromechanical device in order to generate a sound pressure in a mechanically more flexible manner. For this purpose, the actuator may comprise structures enclosing a variable cavity volume within a cavity/void in the layers of the layered system of the microelectromechanical device. The actuator comprises, for example, a pair of legs/fins which are connected to one another by means of (flexible) connecting structures (e.g. at the ends of the legs/fins) and thus form a lateral surface defining the variable cavity volume within the cavity of the microelectromechanical device. By deflecting the legs/fins, the cavity volume can be changed and a sound pressure can be generated.

For example, the actuator may comprise a planar first leg and a planar second leg both extending substantially in the first direction (y) and a second direction (z) perpendicular to the first direction and oppositely arranged in a third direction (x) perpendicular to the first direction (y) and the second direction (z). These two legs may be connected by means of a first connecting structure and a second connecting structure such that the first leg, the second leg, the first connecting structure, and the second connecting structure enclose a variable cavity volume within the cavity to generate a sound pressure.

Some embodiments relate to a microelectromechanical device for generating a sound pressure. The sound pressure may be, for example, an acoustic sound pressure which is in the audible range or in the ultrasonic range. The microelectromechanical device may be implemented in a microelectromechanical system (MEMS). The device comprises a layered system comprising a plurality of layers. The layers of the layered system may comprise: a planar lid, a planar bottom, and sidewalls arranged to enclose a cavity between the lid and the bottom. Furthermore, one or more movable actuators are formed in the cavity in the layers of the layered system. The one or more actuators are drivable to generate a sound pressure. Each of the actuators may comprise: a planar first leg and a planar second leg both extending substantially in the first direction (y) and a second direction (z) perpendicular to the first direction and oppositely arranged in a third direction (x) perpendicular to the first direction (y) and the second direction (z), and a first connecting structure and a second connecting structure connecting respective opposite ends of the first leg and the second leg such that the first leg, the second leg, the first connecting structure, and the second connecting structure enclose a variable cavity volume within the cavity to generate a sound pressure. The term “direction” in this disclosure is not always to be understood strictly in the mathematical sense, but may also be understood in the sense of a direction along one of a plurality of spatial axes (left/right, top/bottom, front/back).

In a further exemplary embodiment, a plurality of drive portions are further formed in the layers of the layered system. These drive portions may be configured to move the first leg and the second leg of each actuator independently to change the enclosed cavity volume of the respective actuator. In one exemplary embodiment, a first drive portion is connected to the first leg of an actuator and a second drive portion is connected to the second leg of the actuator. The first drive portion and the second drive portion are configured to respectively move the legs of the actuator in opposite directions in the third direction (x) (i.e. in opposite directions along a spatial axis). By moving the legs of an actuator by means of the two drive portions, the cavity volume can thus be changed and a sound pressure can be generated.

In the exemplary embodiment, for example, the one or more layers of the layered system in which the drive portions are formed may be formed between the one or more layers of the lid and the one or more layers of the one or more actuators, or may be formed in the layers of the lid. For example, the drive of the actuators may thus be formed on the lid side in the layered system. Alternatively or additionally, it is also possible that the one or more layers of the layered system in which the drive portions are formed are located between the one or more layers in which the bottom and the one or more layers of the one or more actuators are formed, or are formed in the layers of the bottom. Accordingly, the drive can also be implemented on the bottom side, or both on the lid side and on the bottom side. A further exemplary alternative implementation provides that the one or more layers of the layered system in which the drive portions are formed are located in the layers in which the actuators are formed.

In a further embodiment of the apparatus, each actuator is connected to at least one of the drive portions via a connecting element. Here, each actuator can be held in the cavity by the connecting element.

According to a further embodiment, the actuators can be suspended on the side walls, for example. Here, a suspension/connection that is based on substance-to-substance bonding or a suspension/connection that is based on form-lock bonding can be provided. For example, each actuator can be connected to at least one side wall of the apparatus via a connecting element and can be held in the cavity by the connecting element.

In a further embodiment, the legs of the one or more actuators can be flexible in the third direction (x). Here, the third direction (x) is not to be understood in the mathematical sense, for example, but is intended to describe a flexibility of the legs normal to the plane spanned by the first and second directions.

According to further embodiments of the apparatus, the respective cavity volume enclosed by an actuator is delimited in the second direction by the lid and the bottom. Here, a gap can be provided between the lid and each actuator and a gap can be provided between the bottom and each actuator. Here, the gap can be dimensioned such that the gap acts as an acoustic filter whose passband is outside the acoustic frequency range in which the apparatus generates the sound pressure. Alternatively or at the same time, the gap can be formed so small that it is fluidically closed, i.e. the viscosity of the fluid (for example air) is no longer sufficient to flow through the gap when the legs of the actuator move.

According to further embodiments, one or more openings can be provided in the lid which are associated with the one or more actuators. Here, each of the actuators can be associated with at least one opening in the lid which is located in the third direction (x) between the first leg and the second leg of the respective actuator and through which the acoustic pressure generated in the respective cavity volume can be emitted by the apparatus.

In further embodiments, one or more openings may (also) be provided in the bottom which are arranged next to the one or more actuators in the third direction (x). For example, at least one opening can be respectively provided in the bottom in the third direction (x) between two actuators which are directly adjacent to each other. In an exemplary implementation, the at least one opening associated with each actuator can be formed in the lid within the area of the cavity volume of the respective actuator extending in the second direction (z) and the third direction (x) (e.g. the smallest area resulting from the movement of the legs).

In further embodiments of the apparatus, the first connecting structure and the second connecting structure of an actuator together with the first leg and the second leg define a deformable lateral surface enclosing the cavity volume in the circumferential direction (x, y) of an axis of the lateral surface extending parallel to the first direction (y).

According to a further embodiment, the first connecting structure and the second connecting structure of an actuator can have a stiffness in the third direction (x) and/or the second direction (z) which is lower than the stiffness of the first leg and the second leg of the actuator in the third direction (x).

In the embodiments of the apparatus, the first connecting structure and the second connecting structure of an actuator can be respectively formed by a joint-like and/or elastic structure.

According to further embodiments, the first connecting structure and the second connecting structure of an actuator can be formed in the layers of the layered structure in which the legs of the actuator are formed.

Further embodiments relate to a microelectromechanical loudspeaker system implemented as a system-on-chip or system-in-package, comprising a microelectromechanical device for generating a sound pressure according to an embodiment described herein.

### BRIEF DESCRIPTION OF THE DRAWINGS

The present description will be better understood from the following detailed description, which is read in light of the accompanying drawings, wherein like reference numerals are used to designate like parts throughout the accompanying description.

FIG. 1 shows a schematic perspective view of a MEMS transducer from WO 2016/202790 A2;

FIGS. 2A and 2B show an exemplary structure of an actuator according to an embodiment;

FIG. 3 shows a further exemplary structure of an actuator according to an embodiment;

FIG. 4 shows a cross-section of a MEMS-based device 400 for generating a sound pressure according to an embodiment;

FIGS. 5A and 5B show cross-sections of the device 400 according to FIG. 4 along the section lines A-A and B-B in FIG. 4 according to an embodiment;

FIGS. 6A and 6B show cross-sections of a device 600 along the section lines A-A and B-B in FIG. 4 according to a further embodiment;

FIGS. 7A and 7B show cross-sections of a device 700 along the section lines A-A and B-B in FIG. 4 according to a further embodiment;

FIG. 8 shows an exemplary shuttle system for driving the actuators in the device 700 in FIGS. 7A and 7B according to an embodiment; and

FIG. 9 shows an exemplary microelectromechanical loudspeaker system according to an embodiment.

### DETAILED DESCRIPTION

Various embodiments are described in more detail below. The microelectromechanical device for generating a sound pressure and/or a loudspeaker system including the microelectromechanical device may be implemented as a chip/die, e.g. as a system-on-chip (SoC) or a system-in-package (SiP).

One aspect of this disclosure is to design an actuator for use in a microelectromechanical device in order to generate a sound pressure in a mechanically more flexible manner. Various embodiments provide for the structures of the actuator to enclose a variable cavity volume (which may also be referred to as a volume-variable partial cavity) within a cavity/void in the layers of the layered system of the microelectromechanical device. For this purpose, the actuator may comprise a pair of legs/fins which are connected to one another by means of (flexible) connecting structures (for example the ends of the legs/fins) and thus form a lateral surface defining a partial cavity of the cavity of the microelectromechanical device. The volume of the partial cavity can be changed in order to generate a sound pressure. In the embodiments shown, the legs/fins of an actuator are drivable or deflectable so that the volume of the partial cavity can be changed. By enclosing a volume-variable partial cavity of the cavity of the microelectromechanical device, the actuator defines its own variable cavity volume, which makes it possible to reduce/prevent acoustic short circuits within the cavity of the microelectromechanical device.

In some of the embodiments, the connecting structures are more flexible or less rigid, i.e. the legs/fins of the actuator and the legs/fins of the actuator are not connected or fastened to the substrate (in particular the side walls of the cavity of the microelectromechanical device), so that a comparatively lower force is required in order to move the legs/fins of the actuator (for example in opposite directions) and thus the desired volume change of the cavity volume defined by the actuator can be implemented. Accordingly, the legs/fins of the actuator or the actuator itself may be suspended “freely” in the cavity of the microelectromechanical device. For example, the legs/fins of the actuator may be connected on the bottom side and/or on the lid side to the drive device that is to move the legs/fins of the actuator by a connecting structure (e.g. a shuttle arrangement (also: carriage arrangement)). The connecting structure may hold the legs/fins of the actuator in the cavity of the microelectromechanical device. According to various embodiments, the actuator may comprise a planar first leg and a planar second leg. The two legs may extend substantially in the first direction (y) and a second direction (z) perpendicular to the first direction and oppositely arranged in a third direction (x) perpendicular to the first direction (y) and the second direction (z). These two legs may be connected by means of a first connecting structure and a second connecting structure such that the first leg, the second leg, the first connecting structure, and the second connecting structure enclose a variable cavity volume within the cavity to generate a sound pressure.

In this disclosure, a structure extending “substantially” in two directions (e.g. in the first direction and second direction) of three mutually perpendicular directions (e.g. a leg of the actuator) means that the structure is (substantially) a plate-shaped or flat structure extending in the two directions. Although such structures extending “substantially” in two directions may have a (substantially) rectangular outline when viewed in a direction perpendicular to the plane spanned by the two directions, the embodiments are not limited thereto and may also comprise any flat structures enabling the desired functionality. “Flat” means that the thickness of the structure in the third direction (different from the first and second direction) is significantly smaller than the extension of the structure in the two directions. Since the microelectromechanical device for generating a sound pressure may be implemented in a MEMS using semiconductor manufacturing processes, the term “substantially” is further used to express that the planes and edges of a structure may not be perfectly flat or straight in a mathematical sense due to tolerances in the manufacturing process.

The embodiments, i.e. also the microelectromechanical sound generating devices mentioned by way of example in the introduction that use a NED, may be implemented for example by means of a silicon-based semiconductor manufacturing process in a layered system. In the manufacture of such microelectromechanical sound generating devices whose actuators use fins (also: legs), the fins/legs of the actuators may be manufactured by etching trenches in a wafer. In this case, the required minimum fin width (in the x-direction) is relatively wide, so that the fins/legs may therefore have a relatively large stiffness (in the x-direction) due to manufacturing. If the fins/legs are connected in a form-fitting manner or clamped on one side or both sides to the substrate (e.g. on the side walls in the cavity of the sound generating device) in order to hold them in the cavity, comparably large forces may be required to deflect the fins/legs of the actuators. An alternative would be to use freely suspended or non-clamped fins. However, the use of such configurations in a microelectromechanical sound generating device may reduce the acoustic performance, since the gaps between the fins and the lid, bottom and side walls of the cavity, which are required to implement free (fin) ends, may cause acoustic short circuits.

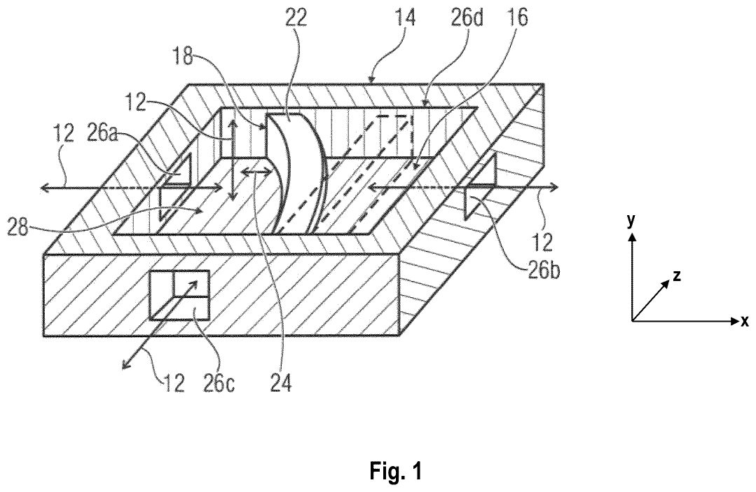

A fin clamped on one side, as shown, for example, in FIG. 1, which corresponds to FIG. 1 of WO 2016/202790 A2 except for the designation of spatial coordinates, moves only very little in the x-direction (lateral movement direction 24) in its clamped region of the fin (deformable element 22) when viewed in the z-direction, compared to the movement that is possible in the x-direction in the fin center or at the non-clamped end of the fin. In addition, the inventors have recognized that the extension of the fin length (in the z-direction) may induce harmonic distortions. As a result, the acoustic performance of the sound transducer is typically reduced. Under certain circumstances, changing the fin stiffness may reduce such harmonic distortions that occur due to a greater fin length and due to the elongation thereof. The generated sound pressure is related to the average deflection of the fin. Some of the embodiments that are described below allow the fins (also: legs) of an actuator to be moved similarly to a piston movement such that the maximum deflection of the fins (in the x-direction in FIG. 1) of the actuator corresponds to the average deflection of the fins of the actuator.

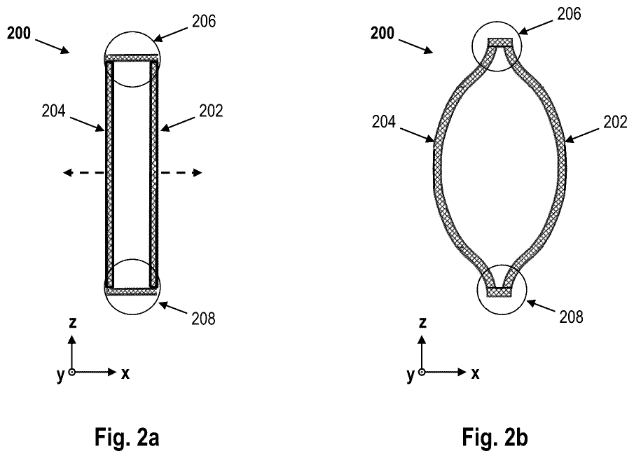

FIGS. 2A and 2B show an exemplary structure of an actuator according to an embodiment. The actuator 200 comprises a first leg 202 and a second leg 204. The two legs 202 and 204 extend substantially along the y-direction and z-direction indicated in the figures. The two ends of the actuator 200 are connected to one another by means of a connecting structure 206 and a connecting structure 208. In the exemplary embodiment shown, the connecting structures 206 and 208 extend substantially in the X-direction and Y-direction. In the exemplary embodiment of FIGS. 2A and 2B, the connecting structure 206 and the connecting structure 208 are shown by way of example as a flat structure connecting the respective ends of the legs 202 and 204 of the actuator 200 to one another. The connecting structures 206 and 208 and the legs 202 and 204 can have substantially the same height (in the Y-direction). The connecting structures 206 and 208 together with the legs 202 and 204 form a lateral surface enclosing a cavity volume in the circumferential direction (x, y) of an axis of the lateral surface extending parallel to the first direction (y). If a plurality of these actuators 202 are provided in a cavity of a MEMS-based device for generating sound, the individual actuators 200 define partial cavities whose variable volume is defined by the lateral surface. The two legs 202 and 204 of the actuator 200 can be deflected by means of a drive device. This is shown by way of example in FIG. 2B. In the exemplary embodiment shown, the two legs 202 and 204 are moved in opposite directions in the lateral direction (X-direction) in order to change the enclosed cavity volume. As a result, the fluid (for example air) defined in the cavity volume can be “modulated” and the desired sound pressure can thus be achieved. In the exemplary embodiment shown in FIG. two, both legs, i.e. the legs 202 and 204, are deflected.

However, it is also conceivable that only one of the two legs 202, 204 is moved to modulate the fluid in the cavity volume, wherein this reduces the maximum volume change of the cavity volume with the same lateral deflection of the leg 202, 204 and thus also the maximum possible sound pressure. In other words, in this alternative, in order to produce the same volume change, the one leg 202, 204 would have to be deflected approximately twice as far in the lateral direction (X-direction) in comparison with the variant shown in FIG. 2B in order to achieve the same volume change.

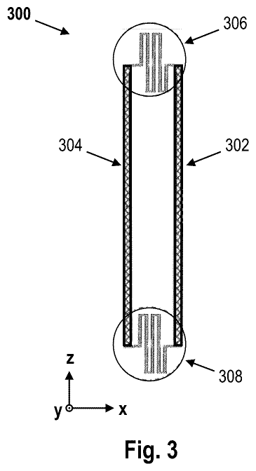

FIG. 3 shows a further exemplary structure of an actuator according to an embodiment, in which an exemplary, spring-like structure of the connecting elements 306, 308 is used, which connect the two ends of the legs 302, 304 lying opposite one another in the lateral direction (X-direction) to one another and thus form a lateral surface comprising a cavity volume.

The lateral surface defining the cavity volume (which can be changed by movement of the legs 202, 204 or 302, 304) should enable a volume change as large as possible utilizing a drive force as small as possible. For this reason, the two connecting structures 206, 208 or 306, 308 of the actuator 200, 300 can have a stiffness in the X-direction and/or in the Z-direction which is lower than the stiffness of the legs 202 and 204 or 306 and 308 of the actuator 200, 300 in the X-direction. The connecting structures 206, 208 or 306, 308 of the actuator 200, 300 are not restricted to a special embodiment, but can be implemented in a wide variety of embodiments. The connecting structures 206, 208 or 306, 308 of the actuator 200, 300 can be formed, for example—similarly to FIG. 3—by a joint-like and/or elastic structure. The aim of the embodiment of the connecting elements is to achieve a structure which can be deformed with as little force as possible. In the use of semiconductor processes for designing the connecting elements and against the background of miniaturization of the MEMS-based apparatuses containing the actuators, it is advantageous if the connecting elements can be implemented on as small a chip area as possible. The minimum width of the etchable trenches and thus also the minimum structure width can be limited or predefined due to geometry of the structures and/or process limitations.

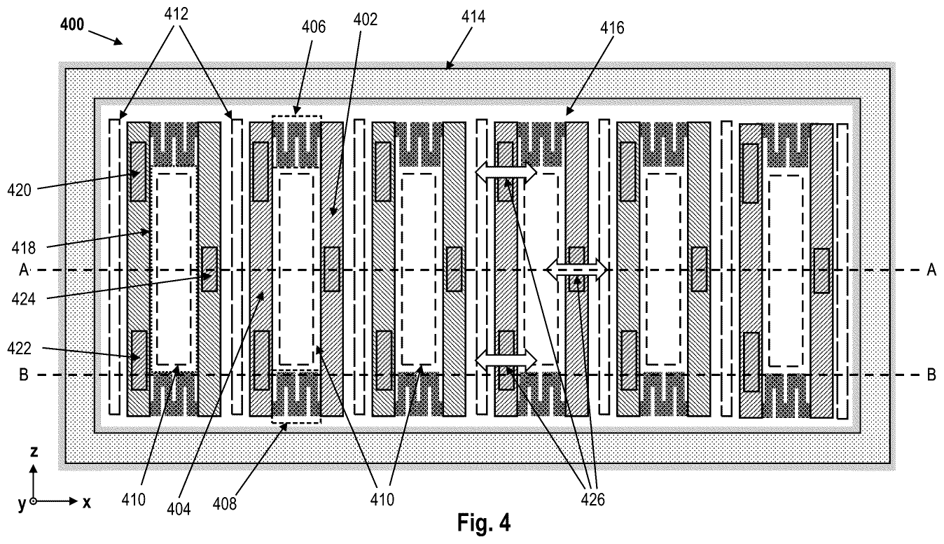

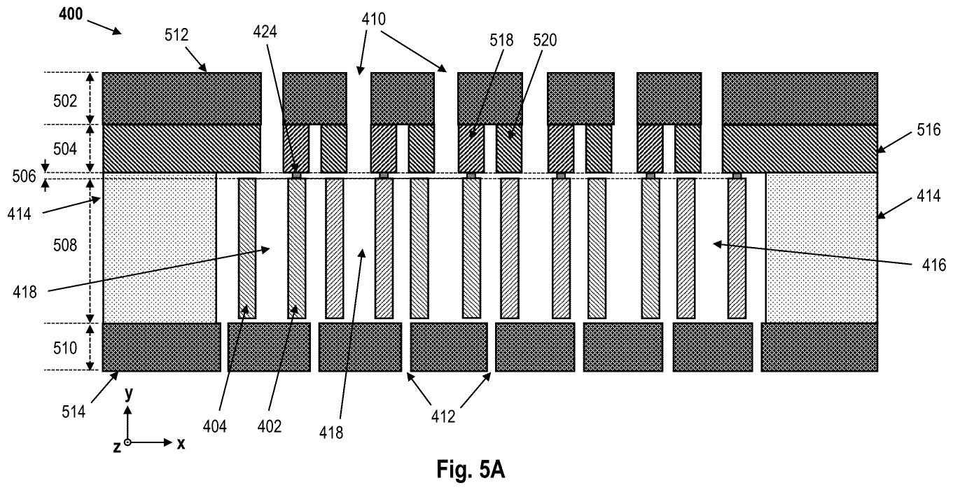

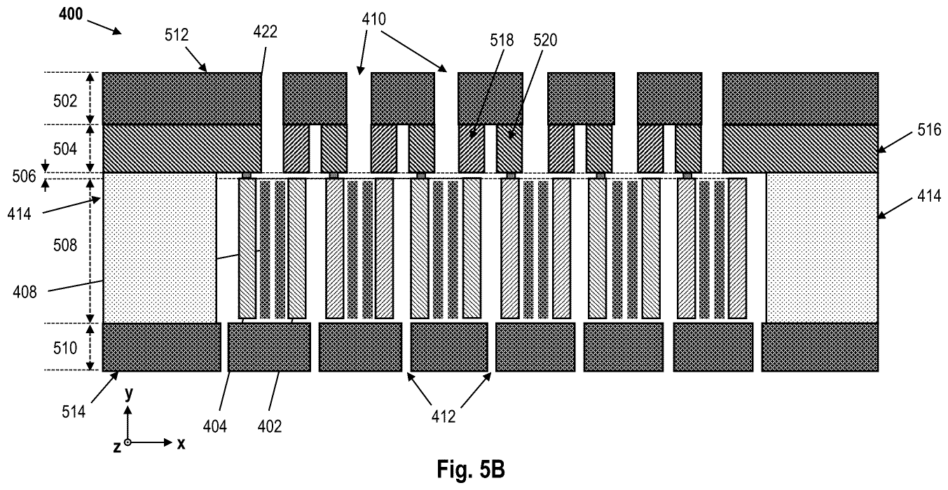

FIG. 4 shows a cross-section (in the x-z plane) of a MEMS-based device 400 for generating a sound pressure according to an embodiment. FIGS. 5A and 5B show cross-sections of the device according to FIG. 4 along the section lines A-A and B-B in FIG. 4 according to an embodiment. FIG. 4 can be considered as a section through the one or more shuttle layers 506 (see FIG. 5A) in the x-z plane, wherein, however, still further features of the MEMS-based device 400 located outside this plane are shown. It is assumed purely for illustration that in the shown embodiment the MEMS-based device 400 is implemented in a layered system that can be manufactured for example by means of a silicon-based semiconductor process. However, the disclosure is not limited thereto. The layered system comprises a plurality of layers. In each case one or more of the layers of the layered system can be functionally/logically grouped into layer regions 502, 504, 506, 508 and 510. The stack of layers can have a (total) height (y-direction) of (approximately) 800 μm to (approximately) 1,700 μm. The layer region 504 and optionally further the layer region 506 can also be considered as partial regions of the layer region 502. The layers of the layer regions 502, 504, 506, 508 and 510 of the layered structure can comprise different materials and/or material combinations, in particular layers that are compatible with semiconductor processes, such as silicon, gallium arsenide or the like. Doping materials can be included at least locally and/or additional materials can be provided, such as conductive materials such as metals. Alternatively or additionally, electrically insulating materials can also form at least parts of a layer, such as nitride and/or oxide materials.

The layers of the layered system comprise the following elements of the device 400. A planar lid 512 of the device 400 is formed in the layer region 502 of the device 400. The layer region 502 of the lid 512 can have a height (y-direction) of approximately 200 μm to 400 μm, for example, but the disclosure is not limited thereto. In the exemplary embodiment shown, a further layer region 504, which can be described as a drive plane 516, is provided, lying therebelow in the Y-direction. This drive plane 516 can comprise, for example, one or more drive devices with which the legs 402, 404 of the different actuators of the device 400 can be deflected. The two legs 402, 404 of an actuator are indicated by the use of the same hatching for the two legs. The exact configuration of the drive devices in the drive plane 516 and also their positioning in the x-z plane of the layer region 504 is not restricted to the specific embodiment shown. In FIGS. 5A and 5B, it is assumed by way of example that the individual legs 402, 404 of the different actuators can be moved individually with a drive device laterally in the X-direction. In this case, the two legs 402, 404 of each actuator are moved either towards one another or away from one another by the corresponding drive devices in order to change the enclosed cavity volume 418 of the respective actuator. In FIGS. 5A and 5B, a layer region 506 can be provided below the layer region 504. The layer region 506 includes connecting elements connecting the respective drive devices in the drive plane 516 to the associated legs 402, 404 of the actuators. These connecting elements are indicated in FIGS. 5A and 5B by the reference numerals 420, 422 and 424. The layer regions 504 and 504 can have a height (y-direction) of only approximately 30 μm to 75 μm, for example, but the disclosure is not limited thereto.

The actuators of the device 400 are formed in the layer region 508. The layer region 508 can have a height (y-direction) of approximately 400 μm to 750 μm, for example, but the disclosure is not limited thereto. The actuators can be formed by way of example as shown in FIGS. 2A, 2B and 3. The side walls 414 are formed in the layer region 508 at both lateral ends of the device 400. Parts of the side walls 414 of the device 400 can be associated with the layer region 506 and/or the layer region 504. A further layer region 510, in which the bottom 514 of the device 400 is formed, is provided below the layer region 508. The layer region 510 of the bottom 514 can have a height (y-direction) of approximately 200 μm to 400 μm, for example, but the disclosure is not limited thereto.

The lid 512 (to be precise, layer regions 502, 504 and 506), the bottom 514 (layer region 510) and the side walls (layer region 508) enclose a cavity 416 in which actuators 200, 300 are positioned. As described in conjunction with FIGS. 2A, 2B and 3, each actuator 200, 300 comprises two legs 402, 404, both of which extend substantially in the Y-direction and a Z-direction perpendicular to the Y-direction. The legs 402, 404 are arranged oppositely in an X-direction perpendicular to the Y-direction and the Z-direction. The 402, 404 are connected by means of the connecting structures 406, 408 such that each actuator encloses a variable cavity volume 418 within the cavity 416 of the device 400 to generate a sound pressure.

Within the lateral surface cross-sectional area (x-z plane), which is defined by an actuator 200, 300, outlet openings of the holes 410 are located in the lid 512 (in particular, layer regions 502, 504 and 506), which lead the sound pressure generated in the cavity volume 418 of each actuator 200, 300 by the movement (see arrows 426) of the legs 402, 404 to the outside. In the exemplary embodiment shown, an outlet opening 410 is associated with each actuator 200, 300. However, it is also possible to provide a plurality of outlet openings 410 for each of the actuators 200, 300. Further openings or holes 412 are located in the bottom 514 (layer region 510) of the device 400 between the actuators 200, 300 or between the lateral side walls 414 and the laterally outer actuators 200, 300. It is also possible here to provide a plurality of openings or holes 412 in the Z-direction in the bottom 514 of the device 400.

The cavity volume 418 enclosed by an actuator 200, 300 is delimited in the Y-direction by the lid 512 (in particular, by the layer region 506) and by the bottom 514. A gap is provided between the actuators 200, 300, in particular between the ends of the legs 402, 404 (and the connecting structures 406, 408) and the lid-side and bottom-side structures of the device 400, viewed in the Y-direction. This gap can be dimensioned such that the gap acts as an acoustic filter (e.g., bandpass or lowpass) whose passband is outside the acoustic frequency range in which the apparatus 400 generates the sound pressure. By enclosing a volume-variable partial cavity 418 of the cavity 416 of the device 400, each actuator defines its own variable cavity volume 418, which makes it possible to reduce acoustic short circuits within the cavity of the microelectromechanical device 400 even in the case of larger gap widths compared to the prior art.

In the exemplary embodiment of FIGS. 4, 5A and 5B, the legs 404 of the actuators 200, 300 located to the left in the lateral direction are each connected to the drive devices in the drive layer 516 by means of two connecting elements 420, 422. The legs 402 of the actuators 200, 300 located to the right in the lateral direction are each connected to drive devices in the drive layer 516 by means of a connecting element 424. However, this embodiment is to be regarded as purely exemplary and not restrictive. Each of the legs 402, 404 of each actuator 200, 300 can be connected to corresponding drive devices in the drive layer 516 by means of one or more connecting elements 420, 422, 424.

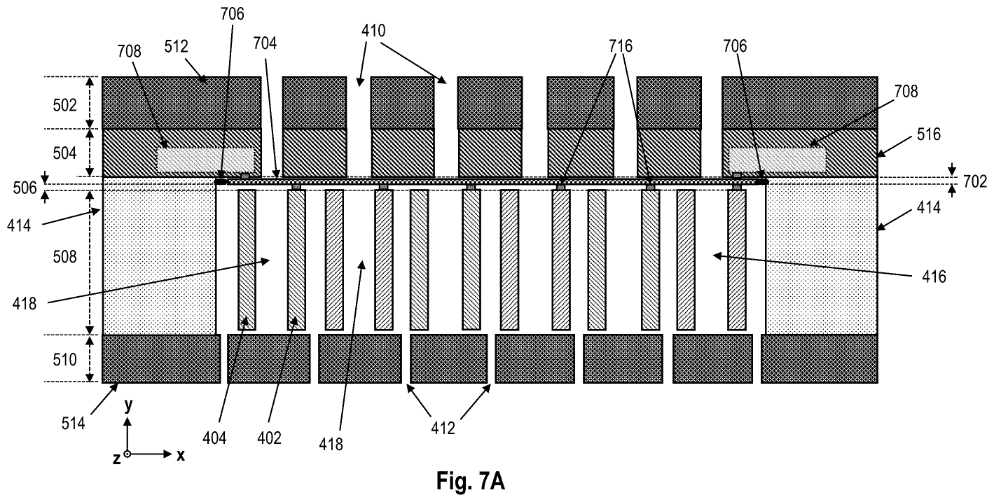

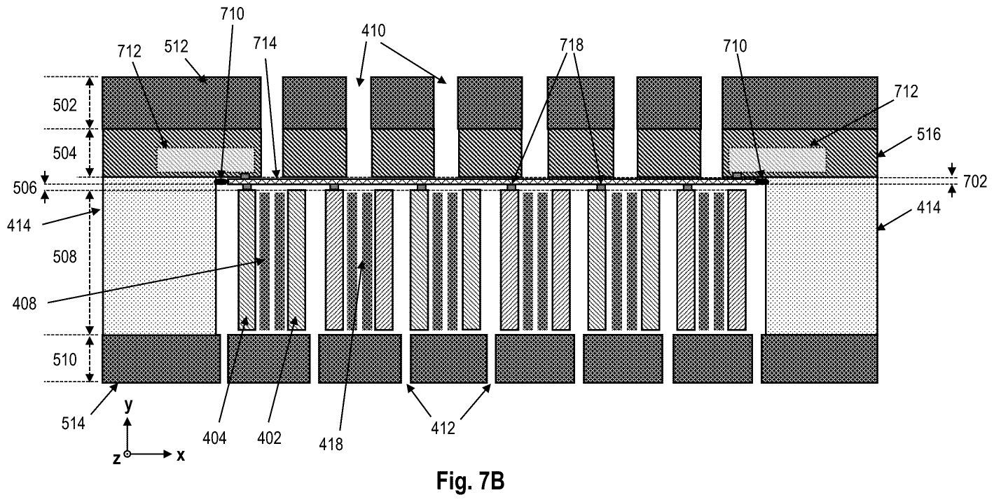

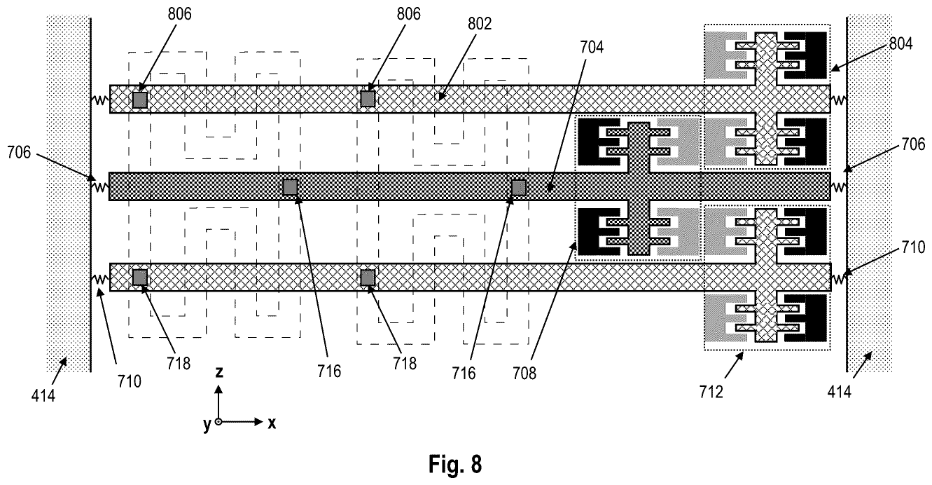

As can be seen from FIG. 4, in contrast to the example shown in FIG. 1, the legs 402, 404 of the actuators 200, 300 are not rigidly connected on one side or on both sides to one or more side walls 414 of the device 400. According to an embodiment, the actuators 200, 300 are suspended in the cavity 416 of the device 400 without such a rigid connection of the legs 402, 404 to the side walls 414. For example, the actuators can be connected to the side walls 414 by means of correspondingly designed connecting elements 406, 408 (not shown in FIG. 4). An alternative mounting of the actuators 200, 300 in the cavity 416 of the MEMS-based device 400 (or device 600) is described below in conjunction with FIGS. 7A, 7B and 8.

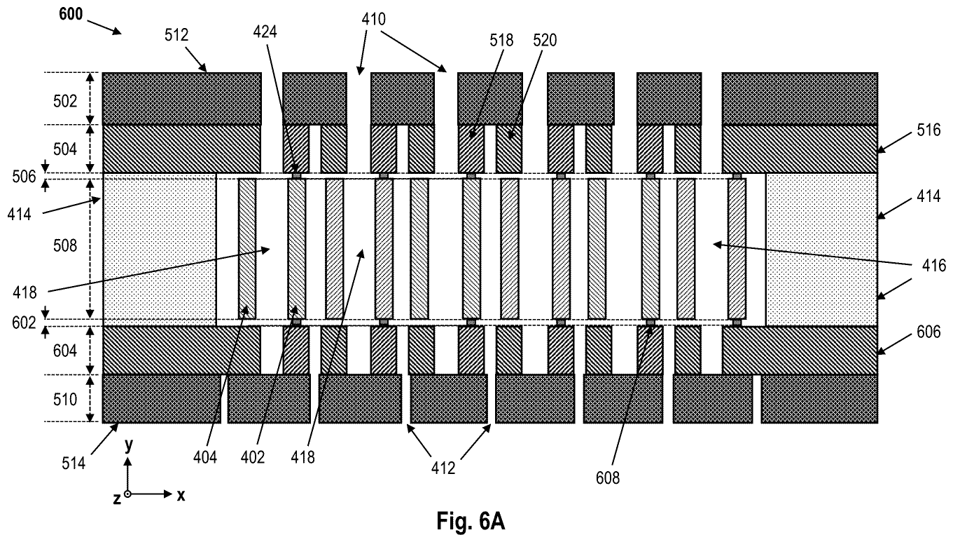

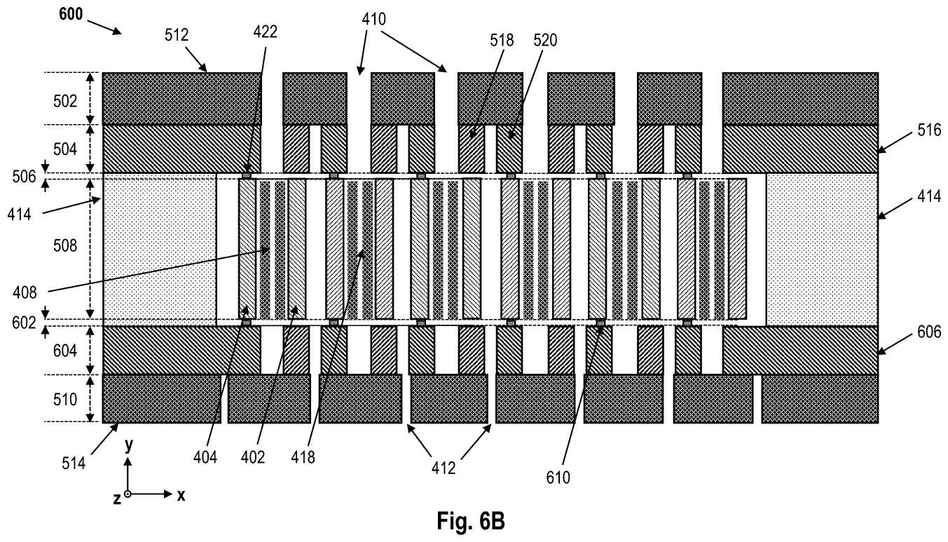

FIGS. 6A and 6B show cross-sections of the device 600 along the section lines A-A and B-B in FIG. 4 according to a further embodiment. The MEMS-based device 600 of FIGS. 6A and 6B substantially corresponds to the device 400 from FIGS. 4, 5A and 5B. In contrast to the device 400, a further bottom-side drive plane 606 in a further layer region 604 is provided in the device 600 in addition to a lid-side drive plane 516. In this case, the drive plane 606 can correspond to the drive plane 516 with regard to function and/or configuration. Furthermore, a layer region 602 is also shown by way of example, which includes the additional connecting elements 608, 610 connecting the legs 402, 404 of the actuators to the drive devices in the drive plane 606. In this case, the layer region 602 can correspond to the layer region 506 with regard to function and/or configuration, wherein the arrangement of the connecting elements 606, 608 can differ from the arrangement of the connecting elements 420, 422, 424 in the layer region 506. Both the layer region 604 and optionally further the layer region 602 can also be considered as part of the layers of the bottom 514 (or part of the layer region 510). By using two drive planes 516, 606, it is possible to implement higher forces for the lateral movement (X-direction) of the legs 402, 404 with substantially unchanged volume of the MEMS-based device 600. As a result, the sound pressure of the device 600 can be increased by approximately +6 dB with respect to the device 400.

FIGS. 7A and 7B show cross-sections of a further MEMS-based device 700 for generating a sound pressure according to an embodiment. The cross-section of the device 700 can also be understood as a cross-section along the section lines A-A and B-B in FIG. 4. In contrast to the devices 406 100, which were discussed in conjunction with FIGS. 4, 5A, 5B, 6A and 6B, the device 701 uses a “shuttle system” for driving and for mounting the actuators 200, 300 in the cavity 416 of the device 700. The two legs 402, 404 of each actuator 200, 300 are connected to different shuttles 704, 714 via corresponding connecting elements 716, 718. The shuttles 704, 714 are in turn connected to respectively associated drive devices 708, 712 by means of which the shuttles 704, 714 can be moved back and forth laterally (in the X-direction). This movement of the shuttles 704, 714 is transmitted via the connecting elements 716, 716 to the actuators 402, 404, which are thereby also deflected in the lateral direction (X-direction). The shuttles 704, 714 can accordingly be considered as further connecting elements by means of which the drive force provided by the drive elements 708, 712 can be transmitted to a plurality of legs 402, 404 of the actuators 200, 300 and enables a lateral movement of the legs 402, 404.

The shuttles 704, 714 are connected at their lateral ends to the lateral side walls 414 of the device 700 via a resilient/springy connecting structure 706, 710. The connecting structures 706, 710 are designed such that the shuttles 704, 714 hold the actuators 200, 300 connected to them within the cavity 416 of the device 700 in the x-z plane, but are designed similar to a spring in order to enable the required lateral deflection of the shuttles 704, 714. According to a purely exemplary embodiment, the shuttles 704, 714 can be moved in the X direction by the drive devices 708, 712 in the range between 1 μm and 20 μm, preferably 1 μm and 10 μm. The movement of the shuttles 704, 714 takes place in opposite directions: if the one or more shuttles 704 connected to first legs 402 of the actuators 200, 300 are moved, for example, to the left in the lateral direction, the one or more shuttles 714, which are connected to the other, second legs 404 of the actuators 200, 300, move laterally in the opposite direction. This is also shown by way of example in FIG. 8.

The shuttles 704, 714 may be part of the layered system of the MEMS-based device 700 and may be formed in a shuttle plane 702 comprising one or more layers of the layered system. The shuttle plane 702 may be formed, for example, between the connecting region 506 and the drive plane 516 (layer region 504). Like the layer regions 504 and 506, the shuttle plane 702 may also be considered as part of the lid 512. Furthermore, it is also possible, analogously to the embodiment in FIGS. 6A and 6B, to form an additional shuttle system with further shuttles between the layer regions 602 and 604, such that a drive of the actuators 200, 300 on the bottom side is also made possible.

The use of one or more shuttle systems may offer the advantage here that the drive devices 708, 712 can be positioned and formed in a more flexible manner in the lateral direction (X-direction) and in the depth direction (Z-direction). In FIGS. 7A and 7B, the drive devices 708, 712 are implemented offset laterally outward in the drive plane 516 in the region of the side walls 414. The drive devices 708, 712 may thus be formed, for example, in regions of the layer system that are not otherwise functionally used (e.g. in the Y-direction in the region of the side walls or in parts of the lid/bottom), such that, under certain circumstances, the overall height of the MEMS can be reduced while the volume of the cavity 416 remains the same, and a sufficiently high, desired drive force is nevertheless available. It is also conceivable for the drive devices 708, 712 to be implemented at least partially, completely, alternatively or additionally also in regions of the layers of the layer region 504 or 604 and optionally also of the layer region 502 or 510 other than those shown in FIGS. 7A and 7B. For example, the drive devices could also alternatively or additionally be implemented above the actuators in the layers of the layered system.

FIG. 8 shows an exemplary shuttle system for driving the actuators in the device 700 in FIGS. 7A and 7B according to an embodiment. It is assumed here purely by way of example that the shuttle system is implemented on the lid side. Alternatively or additionally, the shuttle system could also be implemented on the bottom side. According to the example of FIG. 4, it is assumed here by way of example that one of the legs 402 of each actuator is connected to the shuttle 704 by a connecting element 716 (424), while the other leg 404 of each actuator is connected to two shuttles 714, 802 by two connecting elements 718, 806 (420, 422). Each of these three shuttles 704, 714, 802 is driven here by a drive device 708, 712, 804. If a shuttle system on the bottom side is additionally used, it could be ensured that in the exemplary embodiment each leg 402, 404 is connected to three shuttles and is driven, such that all legs 402, 404 are deflectable with an identical maximum force.

The exact configuration of the drive devices 708, 712, 804 is not relevant to the idea of shuttle drive. For example, the drives may be electrostatic, piezoelectric and/or thermomechanical electrodes, which realize a deformation of the fins of the actuators based on an applied potential. For example, the drive devices 708, 712, 804 could each have a plurality of electrostatic, piezoelectric and/or thermomechanical drive elements, which drive the respective shuttle 704, 714, 802. For example, the drive device can be implemented according to the drive shown in U.S. patent application Ser. No. 18/210,640 filed on Jun. 15, 2023 that is based on and claiming priority of European patent application EP 22180979.1 filed on 24 Jun. 2022, both incorporated herein by reference.

It is conceivable that not all actuators are connected to a shuttle pair. It is likewise possible that individual shuttle pairs (or shuttle groups) drive different subgroups of the actuators.

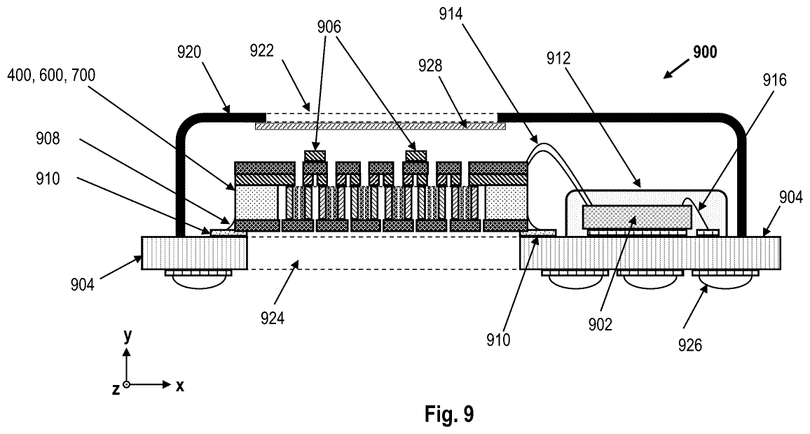

A further aspect of this disclosure is the use of a MEMS-based device for generating sound according to one of the embodiments described herein in a microelectromechanical loudspeaker system. Such a loudspeaker system could, for example, be implemented as a system-on-chip or system-in-package. FIG. 9 shows an exemplary microelectromechanical loudspeaker system 900 according to an embodiment. The microelectromechanical loudspeaker system 900 comprises a microelectromechanical acoustic MEMS-based device 400, 600, 700 for generating sound according to one of the various embodiments described herein. In this embodiment, the sound pressure generated by the device 400, 600, 700 can be sound, ultrasound or a voice, for example, but the sound pressure is not limited to sound in the audible frequency range of humans. The microelectromechanical loudspeaker system 900 can be used in a headphone, an in-ear headphone, a near-field loudspeaker, a hearing aid, etc., for example.

In the exemplary loudspeaker system 900, the bottom 514 of the MEMS-based device 400, 600, 700 can be mounted on a top side of a carrier, such as a printable circuit board (PCB) 904, for example. The PCB 904 can be provided with an opening or cutout region 924. The microelectromechanical acoustic MEMS-based device 400, 600, 700 is mounted on the PCB 904 in a region on the top side of the PCB 904 which corresponds to the opening or cutout region 924, such that the opening or cutout region 924 is provided substantially below the bottom 514 of the MEMS-based device 400, 600, 700. An edge region of the bottom 516 of the MEMS-based device 400, 600, 700 can overlap (at least partially) with the PCB 904, and the MEMS-based device 400, 600, 700 can be mounted on the top side of the PCB 904 at the edge region, e.g. using an adhesive 910. The adhesive 910 can optionally be an electrically conductive adhesive, such that the adhesive 910 facilitates the electrical connection between the MEMS-based device 400, 600, 700 and conductive paths in the PCB 904. Furthermore, a seal 908 can be provided around the outer edges of the MEMS-based device 400, 600, 700.

The PCB 904 can provide electrical connections for conducting the static/variable potentials required to drive the actuators 200, 300. For this purpose, one or more drive devices in the drive plane 516 can process a sound signal or an audio signal received from a processing unit 902 of the microelectromechanical loudspeaker system 900. The sound or audio signal can be either a digital signal or an analogue signal. The processing unit 902 can implement a control system configured to control the acoustic pressure generation of the MEMS-based device 400, 600, 700. The functionality of the processing unit 902 can be provided by several discrete circuit components, e.g. more than one DSP, ASIC, FPGA, PLD, or a combination thereof, all of which can be mounted on the PCB 904 using the techniques described below.

In the example shown in FIG. 9, the processing unit 902 is mounted on top of the PCB 904 using known bonding techniques (e.g. wire bonding, chip bonding, ball bonding, etc.) to enable the communication of signals between the processing unit 902 and the MEMS-based device 400, 600, 700 through the conductive paths provided in the PCB 904 and to drive the actuators 200, 300. Alternatively or additionally, the processing unit 902 could also be connected to the MEMS-based device 400, 600, 700 by bonding wires 914 to enable the communication of signals and to drive the actuators 200, 300. Further, optionally or alternatively, bonding wires 916 could be used for the electrical connection of the processing unit 902 and the conductive paths of the PCB 904. The processing unit 902 and the optional bonding wires 914, 916 can be encased in a glob top 912.

The bonding between the processing unit 902 and the conductive paths of the PCB 904 can further connect the processing unit 902 to other device components outside the microelectromechanical loudspeaker system 900, although a bonding (e.g. using grid balls 926) is provided on the other, lower surface side of the PCB 904. For example, the microelectromechanical loudspeaker system 900 can be part of a larger acoustic device, such as part of an in-ear headphone, a hearing aid or the like. Such devices can also provide a back volume for the microelectromechanical loudspeaker system 900.

The MEMS-based device 400, 600, 700 and the processing unit 902 can further be covered with a cover 920. The cover 920 can be a metal cover or plastic cover, for example. The cover 920 can be provided with an acoustic pressure outlet opening 922 in a position above (in y-direction) the MEMS-based device 400, 600, 700, so that the acoustic pressure emitted through the air outlet openings 220 of the MEMS-based device 400, 600, 700 is emitted through the acoustic pressure outlet opening 922 to outside the microelectromechanical loudspeaker system 900. Optionally, a plurality of such acoustic pressure outlet openings 922 could be provided. The area in which the acoustic pressure outlet opening(s) 922 is/are provided can substantially correspond (with regard to position and/or size) to the dimensions of the MEMS-based device 400, 600, 700 in the x-z plane.

In order to prevent dirt particles from entering the cavity around the MEMS-based device 400, 600, 700 and the processing unit 902 formed by the cover 920, an acoustic cloth or gauze 928 (or other suitable acoustic pressure-transparent material) can be used to cover the acoustic pressure outlet opening(s) 922. Optionally, one or more microphones 906 can be positioned next to the openings 410 of the MEMS-based device 400, 600, 700. Further optionally, the microelectromechanical loudspeaker system 900 can implement an active noise cancelling (ANC) function. The microphone(s) 906 detect interference noise and an acoustic pressure emitted through the acoustic pressure outlet opening(s) 410. The processing unit 902 can implement a control system configured to control the acoustic pressure generation of the MEMS-based device 400, 600, 700 based on the acoustic pressure detected by the microphone(s) 906 and the interference noise such that the detected interference noise is suppressed.

As already explained, the MEMS-based device 400, 600, 700 can be manufactured in a layer process using materials known from conventional semiconductor manufacturing. Part of the process flow could be implemented using the method described in the PhD thesis of Latifa Louriki, “Mikromechanischer Prozess zur Herstellung mehrlagiger 3D-MEMS (EPyC-Prozess)” (“Micromechanical Process for Manufacturing Multi-Layer 3D MEMS (EPyC Process)”), filed on 28 Jan. 2020 at the Department of Electrical Engineering and Information Technology of the Technical University of Chemnitz. The PhD thesis is available at https://monarch.qucosa.de/api/qucose/%3A74643/attachment/ATT-0/ and is incorporated herein by reference.

1. A microelectromechanical device for generating a sound pressure implemented in a microelectromechanical system (MEMS), the device comprising:
a layered system comprising a plurality of layers, the layers of the layered system comprising:
a planar lid, a planar bottom, and sidewalls arranged to enclose a cavity between the lid and the bottom; and
one or more actuators movable in the cavity and drivable to generate a sound pressure; and
wherein each actuator comprises:
a planar first leg and a planar second leg both extending substantially in the first direction and a second direction perpendicular to the first direction and oppositely arranged in a third direction perpendicular to the first direction and the second direction; and
a first connecting structure and a second connecting structure connecting respective opposite ends of the first leg and the second leg such that the first leg, the second leg, the first connecting structure, and the second connecting structure enclose a variable cavity volume within the cavity to generate a sound pressure.

2. The microelectromechanical device of claim 1, wherein the layers of the layered system further comprise a plurality of drive portions configured to move the first leg and the second leg of each actuator independently to change the enclosed cavity volume of the respective actuator.

3. The microelectromechanical device of claim 2, wherein a first drive portion is connected to the first leg of an actuator and a second drive portion is connected to the second leg of the actuator, and
wherein the first drive portion and the second drive portion are configured to respectively move the legs of the actuator in the opposite direction in the third direction.

4. The microelectromechanical device of claim 2, wherein the one or more layers of the layered system in which the drive portions are formed are formed between the one or more layers of the lid and the one or more layers of the one or more actuators, or are formed in the layers of the lid.

5. The microelectromechanical device of claim 2, wherein the one or more layers of the layered system in which the drive portions are formed are located between the one or more layers in which the bottom and the one or more layers of the one or more actuators are formed, or are formed in the layers of the bottom.

6. The microelectromechanical device of claim 2, wherein each actuator is connected to at least one of the drive portions via a connecting element and is held in the cavity by the connecting element.

7. The microelectromechanical device of claim 2, wherein each actuator is connected to at least one side wall of the apparatus via a connecting element and is held in the cavity by the connecting element.

8. The microelectromechanical device of claim 1, wherein the legs of the one or more actuators are flexible in the third direction.

9. The microelectromechanical device of claim 1, wherein the respective cavity volume enclosed by an actuator is delimited in the second direction by the cover and the bottom, wherein a gap is provided between the cover and each actuator and a gap is provided between the bottom and each actuator.

10. The microelectromechanical device of claim 1, wherein the gap is dimensioned such that the gap acts as an acoustic filter whose passband is outside the acoustic frequency range in which the apparatus generates the sound pressure.

11. The microelectromechanical device of claim 1, wherein one or more openings are provided in the lid which are associated with the one or more actuators,
wherein each of the actuators is associated with at least one opening in the lid which is located in the third direction between the first leg and the second leg of the respective actuator and through which the acoustic pressure generated in the respective cavity volume can be emitted by the apparatus.

12. The microelectromechanical device of claim 1, wherein one or more openings are provided in the bottom which are arranged next to the one or more actuators in the third direction.

13. The microelectromechanical device of claim 12, wherein at least one opening is respectively provided in the bottom in the third direction between two directly adjacent actuators.

14. The microelectromechanical device of claim 11, wherein the at least one opening associated with each actuator is formed in the lid within the area of the cavity volume of the respective actuator extending in the second direction and the third direction.

15. The microelectromechanical device of claim 1, wherein the first connecting structure and the second connecting structure of an actuator together with the first leg and the second leg define a deformable lateral surface enclosing the cavity volume in the circumferential direction of a jacket axis extending parallel to the first direction.

16. The microelectromechanical device of claim 1, wherein the first connecting structure and the second connecting structure of an actuator have a stiffness in the third direction and/or the second direction which is lower than the stiffness of the first leg and the second leg of the actuator in the third direction.

17. The microelectromechanical device of claim 1, wherein the first connecting structure and the second connecting structure of an actuator are respectively formed by a joint-like and/or elastic structure.

18. The microelectromechanical device of claim 1, wherein the first connecting structure and the second connecting structure of an actuator are formed in the layers of the layered structure in which the legs of the actuator are formed.

19. A microelectromechanical loudspeaker system implemented as a system-on-chip or system-in-package, comprising a microelectromechanical device for generating a sound pressure, said microelectromechanical device comprising:
a layered system comprising a plurality of layers, the layers of the layered system comprising:
a planar lid, a planar bottom, and sidewalls arranged to enclose a cavity between the lid and the bottom; and
one or more actuators movable in the cavity and drivable to generate a sound pressure; and
wherein each actuator comprises:
a planar first leg and a planar second leg both extending substantially in the first direction and a second direction perpendicular to the first direction and oppositely arranged in a third direction perpendicular to the first direction and the second direction; and
a first connecting structure and a second connecting structure connecting respective opposite ends of the first leg and the second leg such that the first leg, the second leg, the first connecting structure, and the second connecting structure enclose a variable cavity volume within the cavity to generate a sound pressure.
